(19) United States
(12) Patent Application Publication
(10) Pub. No.: US 2009/0087990 A1
(43) Pub. Date: Apr. 2, 2009

(54) Manufacturing method, manufacturing apparatus, control program and program recording medium of semiconductor device

(75) Inventors: Koichi Yatsuda, Nirasaki-shi (JP); Eiichi Nishimura, Nirasaki-shi (JP)

Correspondence Address: MASUVALLEY & PARTNERS, 8765 AERO DRIVE, SUITE 312, SAN DIEGO, CA, 92123, US

(73) Assignee: TOKYO ELECTRON LIMITED, Minato-ku (JP)

(21) Appl. No.: 12/284,749

(22) Filed: Sep. 24, 2008

Related U.S. Application Data
(60) Provisional application No. 60/991,507, filed on Nov. 30, 2007.

(30) Foreign Application Priority Data
Sep. 28, 2007 (JP) 2007-253409
Apr. 17, 2008 (JP) 2008-107467

(51) Int. Cl. H01L 21/311

(52) U.S. Cl. 438/694; 156/345.26; 257/E21.215

(57) ABSTRACT

A manufacturing method of a semiconductor device, which etches a layer to be etched on a substrate into a predetermined pattern based on a first pattern of photoresist produced by exposing and developing a photoresist film, the manufacturing method including the steps of forming an SiO₂ film on a first pattern of the photoresist, etching the SiO₂ film so that the SiO₂ may remain only in a side wall section of a first pattern of the photoresist, removing a first pattern of the photoresist, and forming a second pattern of the SiO₂ film.

### BACKGROUND

1. Technical Field

The present invention relates to a manufacturing method of a semiconductor device, a manufacturing apparatus for manufacturing a semiconductor device, a control program, and a storing medium for the program for manufacturing a semiconductor device by etching a layer to be etched on a substrate into a predetermined pattern based on a first pattern of photoresist produced by exposing and developing a photoresist film.

2. Description of the Related Art

Up to now, in manufacturing processes, such as a semiconductor device, etching processing of plasma etching to substrates, such as a semiconductor wafer has been performed to form a fine circuit pattern. In such an etching processing process, an etching mask is formed by performing a photolithography process using photoresist.

In such a photolithography process, in order to respond to the trend to a fine pattern to be formed, various technologies have been developed. There is what is called double patterning as one of them. This double patterning is a pattering process, which is capable of forming an etching mask having a more fine pattern than a case where an etching mask is formed by one patterning by performing two steps of patterning including the first mask pattern formation step and the second mask pattern formation step performed after this the first mask pattern formation step. (For example, refer to Japanese Patent Application Publication No. 2007-027742)

It has been known to perform patterning in a pitch more fine than a pattern of photoresist obtained by firstly exposing and developing a photoresist film by using a SWT (side wall transfer) method, which uses SiO₂ film, Si₃N₄ film, etc. as a sacrificial layer, for example, and forms and uses a mask for both-side side wall portions of one pattern. That is, in this method, a sacrificial layer of the SiO₂ film is etched and patterned first, using a pattern of photoresist. After that, a Si₃N₄, film etc., is formed on a pattern of this SiO₂ film, and etchback is performed so that Si₃N₄ film may remain only in a side wall portion of SiO₂ film. Then, wet etching removes the SiO₂ film and lower layer etching is performed by using the Si₃N₄ remaining film as a mask.

In membrane formation technologies, it may be required that membranes should be formed more at low temperature. With regard to a technology for performing a formation of membranes at low temperature, a method for performing membrane formation with chemicals vapor phase epitaxy, in which membrane formation gas is activated by a heating catalyst body, is known (for example, refer to Japanese Patent Application Publication No. 2006-179819).

In a conventional technology, as described above, there are problems that the number of processes increases, while a process is complicated, a manufacturing cost increases, and productivity becomes worse. In the conventional SWT method, since a wet etching process is required, it becomes a process in which dry etching and wet etching are intermingled. This becomes a factor, which makes a process complicated.

An object of the present invention is to provide a manufacturing method of a semiconductor device, a manufacturing apparatus of a semiconductor device, a control program, and a program store medium which can promote improvement in productivity to solve the conventional problems described above and to perform simplification of a process and reduction of a manufacturing cost comparing with the former.

### SUMMARY OF THE INVENTION

An aspect of the present invention is a manufacturing method of a semiconductor device, which etches a layer to be etched on a substrate into a predetermined pattern based on a first pattern of photoresist produced by exposing and developing a photoresist film. The manufacturing method including the steps of forming an SiO₂ film on a first pattern of the photoresist, etching the SiO₂ film so that the SiO₂ may remain only in a side wall section of a first pattern of the photoresist, removing a first pattern of the photoresist, and forming a second pattern of the SiO₂ film.

Another aspect of the present invention is the manufacturing method of a semiconductor device, wherein the step of forming a SiO₂ film is performed by applying chemical vapor phase epitaxy by using membrane formation gas activated by a heating catalyst body.

Another aspect of the present invention is the manufacturing method of a semiconductor device, further comprising the steps of trimming a first pattern of the photoresist while etching an antireflection film formed from an organic material, which is a lower layer, before forming an SiO₂ film.

Another aspect of the present invention is the manufacturing method of a semiconductor device, wherein a silicon layer, a silicon nitride layer (Si₃N₄) or a silicon oxynitride (SiON) layer, which is a lower layer, is etched by using the second pattern as a mask after the step of forming a second pattern.

Another aspect of the present invention is the manufacturing method of a semiconductor, further comprising the steps of etching an antireflection film formed from inorganic material, which is a lower layer, by using the second pattern as a mask after forming the second pattern, and then, etching an inorganic material film, which is a lower layer than an antireflection film formed from an organic material.

Another aspect of the present invention is the manufacturing method of a semiconductor device, wherein an antireflection film formed from the inorganic material is a SOG (Spin On Glass) film, an LTO (Low Temperature Oxide) film or an SiON film.

Another aspect of the present invention is a manufacturing method of a semiconductor device, which etches a layer to be etched on a substrate into a predetermined pattern, the manufacturing method including the steps of forming a first pattern formed from a plurality of line shaped patterns of photoresist, forming a SiO₂ film on the first pattern, etching the SiO₂ film on the first pattern so that the SiO₂ film on the first pattern may remain only in a side wall section of a first pattern of the photoresist, removing the first pattern and forming a second pattern of the SiO₂ film, etching a first mask structure layer, which is a lower layer, by using the second pattern as a mask, forming a third pattern formed from a plurality of line shaped patterns of photoresist in a direction which crosses perpendicularly with the first pattern, forming a SiO₂ film on the third pattern, etching the SiO₂ film on the third pattern so that the SiO₂ film on the third pattern may remain only in a side wall section of the third pattern, removing the third pattern and forming a fourth pattern of the SiO₂ film, etching a second mask structure layer, which is a lower layer, by using the fourth pattern and the first mask structure layer as a mask, and forming a hole shape in the layer to be etched by using the first mask structure layer and the second mask structure layer as a mask.

Another aspect of the present invention is the manufacturing method of a semiconductor device, wherein the steps of forming an SiO₂ film on the first pattern and etching the first mask structure and forming a second pattern of the SiO₂ film are performed by applying chemical vapor phase epitaxy by using membrane formation gas activated by a heating catalyst body.

Another aspect of the present invention is the manufacturing method of a semiconductor device, further including the steps of trimming the first pattern before forming an SiO₂ film on the first pattern, while etching an antireflection film formed from an organic material, which is a lower layer, and trimming the third pattern before forming a first pattern of the SiO₂ film while etching an antireflection film formed from an organic material, which is a lower layer.

Another aspect of the present invention is the manufacturing method of a semiconductor device, wherein the first mask structure layer is formed from silicon and the second mask structure layer is formed from silicon nitride.

Another aspect of the present invention is a manufacturing apparatus of a semiconductor device, which manufactures a semiconductor device by etching a layer to be etched on a substrate into a predetermined pattern, the manufacturing apparatus including a processing chamber for storing the substrate, a processing gas supply means, which supplies processing gas into the processing chamber and a control section for controlling the processing gas supply means so that the manufacturing method of a semiconductor device is performed within the processing chamber.

Another aspect of the present invention is a control program for operating on a computer and controlling a manufacturing apparatus of a semiconductor device at time of execution so that the manufacturing method of the semiconductor device is performed.

Another aspect of the present invention is a program store medium, which is a medium by which a control program, which operates on a computer, is memorized, and the control program controlling a manufacturing apparatus of a semiconductor device so that the manufacturing method of the semiconductor device is performed at time of execution.

### BRIEF DESCRIPTION OF THE DRAWINGS

FIG. 1 schematically illustrates a process of a first embodiment of the present invention.

FIG. 2 schematically illustrates a process of a second embodiment of the present invention.

FIG. 3 schematically illustrates a process of a third embodiment of the present invention.

FIG. 4 schematically illustrates a process of a fourth embodiment of the present invention.

FIG. 5 schematically illustrates a schematic diagram of the apparatus used for one embodiment of the present invention.

FIG. 6 schematically illustrates the process of a fifth embodiment of the present invention.

FIG. 7 schematically illustrates a plane structure in the process of a fifth embodiment of the present invention.

FIG. 8 schematically illustrates a process of a fifth embodiment of the present invention.

FIG. 9 schematically illustrates the plane structure in the process of a fifth embodiment of the present invention.

FIG. 10 schematically illustrates the plane structure and the section structure in the process of a fifth embodiment of the present invention.

### DETAILED DESCRIPTION OF THE PREFERRED EMBODIMENTS

Hereafter, one embodiment of the present invention will be described with reference to a drawing.

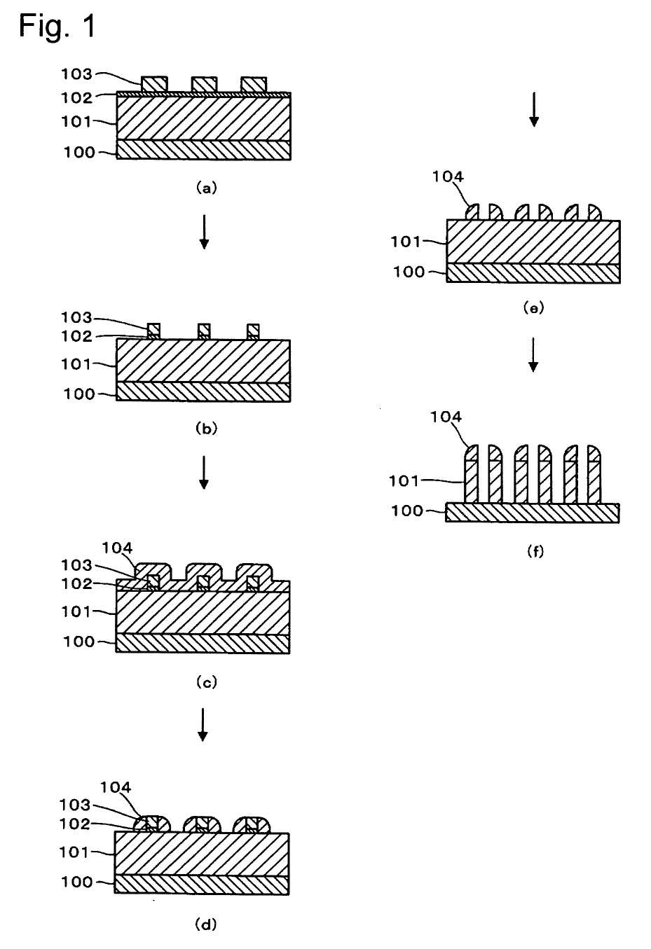

FIG. 1 is a drawing, which expands and schematically illustrates a part of semiconductor wafer related to a first embodiment of the present invention, and illustrates a process of a manufacturing method of a semiconductor device related to the first embodiment. As illustrated in FIG. 1(a), in the first embodiment, an antireflection film (BARC) 102 of an organic material is formed on a polysilicon layer 101 as a layer for aiming at patterning to be etched. A photoresist 103 is formed on this antireflection film (BARC) 102. The Photoresist 103 is patterned by an exposure and development process and formed into a pattern having a predetermined shape. In FIG. 1, numeral 100 denotes a foundation layer provided under the polysilicon layer 101.

FIG. 1(b) illustrates the state where the antireflection film (BARC) 102 is etched while trimming of the above-mentioned photoresist 103 is performed to make line width thin. The plasma etching using oxygen plasma, etc., can perform the processes of performing trimming of the photoresist 103 and etching of the antireflection film (BARC) 102, for example.

Next, as illustrated in FIG. 1(c), a SiO₂ film 104 is formed. As for the photoresist 103, generally, although membranes are formed on the photoresist 103 in this membrane formation process, since the photoresist 103 is weak to high temperature and photoresist collapse occurs, when exposed to high temperature, it is preferred to form membranes at low temperature (for example, about 300 degrees centigrade or lower). In this case, the chemicals vapor phase epitaxy that membrane formation gas is activated by the heating catalyst body can be performed.

Next, as illustrated in FIG. 1(d), the SiO₂ film 104 is etched and the SiO₂ film 104 changes into the state where the SiO₂ film 104 remains only in the side wall section of the pattern of the photoresist 103. This etching can be performed using, for example, mixed gas of CF series gas of CF₄, C₄F₈, CHF₃, CH₃F and CH₂F₂ and Ar gas, or the gas that oxygen is added if needed to this mixed gas.

Next, as illustrated in FIG. 1(e), by ashing using oxygen plasma, etc., the pattern of the photoresist 103 is removed and the pattern by the SiO₂ film 104 which remained in the side wall section is formed.

And as illustrated in FIG. 1(f), a polysilicon layer 101, which is a lower layer, is etched by using the pattern by the SiO₂ above-mentioned film 104 as a mask. This etching can be performed using HBr gas, etc., for example.

The fine pattern by an SWT method can be formed in the above-mentioned first embodiment, without using a sacrificial layer. All etching processes can be carried out according to the dry etching process, without performing wet etching in the middle of the process. Therefore, simplification of the process and reduction of the manufacturing cost can be promoted comparing with the former, and improvements in productivity can be promoted.

The SiO₂ film 104 having a thickness of about 35 nm is to be formed with the chemicals vapor phase epitaxy in which membrane formation gas is actually activated by the heating catalyst body at the process illustrated in FIG. 1(c). Etching on each process is conducted by using the apparatus, which supplies high frequency electric power and performs plasma etching to the top electrode and the lower electrode of an opposite electrode on the following conditions. As a result, a polysilicon layer 101 (about 100 nm (a foundation layer is an oxide film) in thickness) was able to be patterned into a good shape.

(Photoresist 103 of FIG. 1(b) and FIG. 1(e), etching of antireflection film 102)
Etching gas: O₂ (374 sccm)
Pressure: 13.3 Pa (100 mTorr)
Electric power: 600 W (upper portion)/30 W (lower portion)
(Etching of SiO₂ film 104 in FIG. 1(d))
Etching gas: Ar/C4F8 (500 sccm/20 sccm)
Pressure: 5.3 Pa (40 mTorr)
Electric power: 600 W (upper portion)/100 W (lower portion)
(Etching of polysilicon layer 101 of FIG. 1(f))

### (Main Etching)

Etching gas: HBr/O₂ (400 sccm/2 sccm)
Pressure: 4.0 Pa (30 mTorr)
Electric power: 200 W (upper portion)/150 W (lower portion)

### (Exaggerated Etching)

Etching gas: HBr/O₂ (934 sccm/4 sccm)
Pressure: 20.0 Pa (150 mTorr)
Electric power: 650 W (upper portion)/200 W (lower portion)

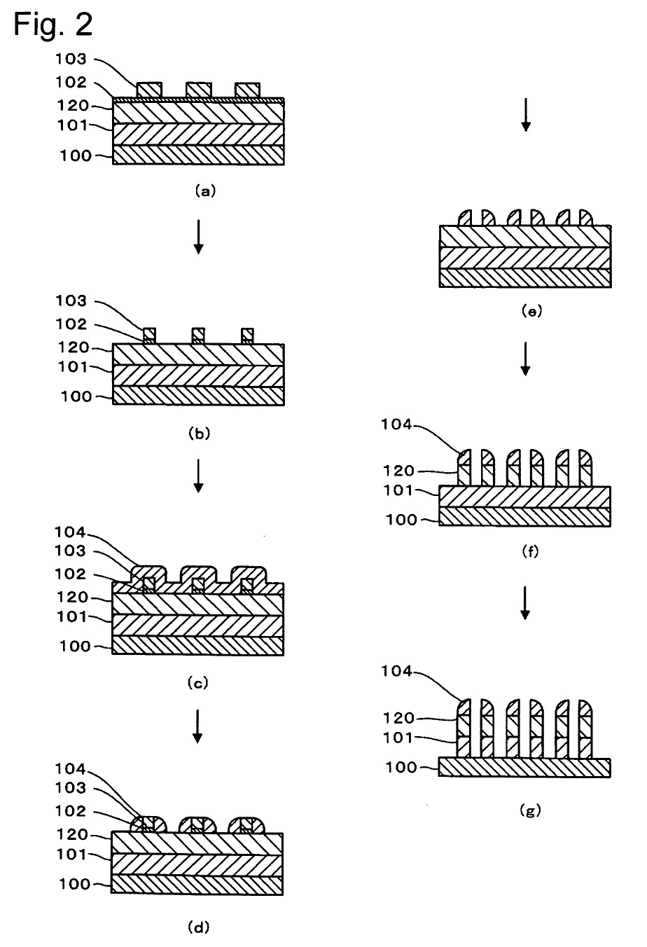

FIG. 2 illustrates a manufacturing process of the semiconductor device of the second embodiment in which another film 120, for example, an Si₃N₄ film, is formed between the polysilicon layer 101 and the antireflection film (BARC) 102 in the above-mentioned first embodiment. In the case of this second embodiment, the process of FIG. 2(a)-FIG. 2(e) is performed as well as the case of the first embodiment illustrated in FIG. 1. And the Si₃N₄ film 120, which is a lower layer, is etched by using the pattern by the SiO₂ film 104 as a mask after this (f). The polysilicon layer 101 is etched by using this Si₃N₄ film 120 as a mask (g). In the case of FIG. 2, an SiON (silicon oxynitride) film may be used instead of the Si₃N₄ film 120.

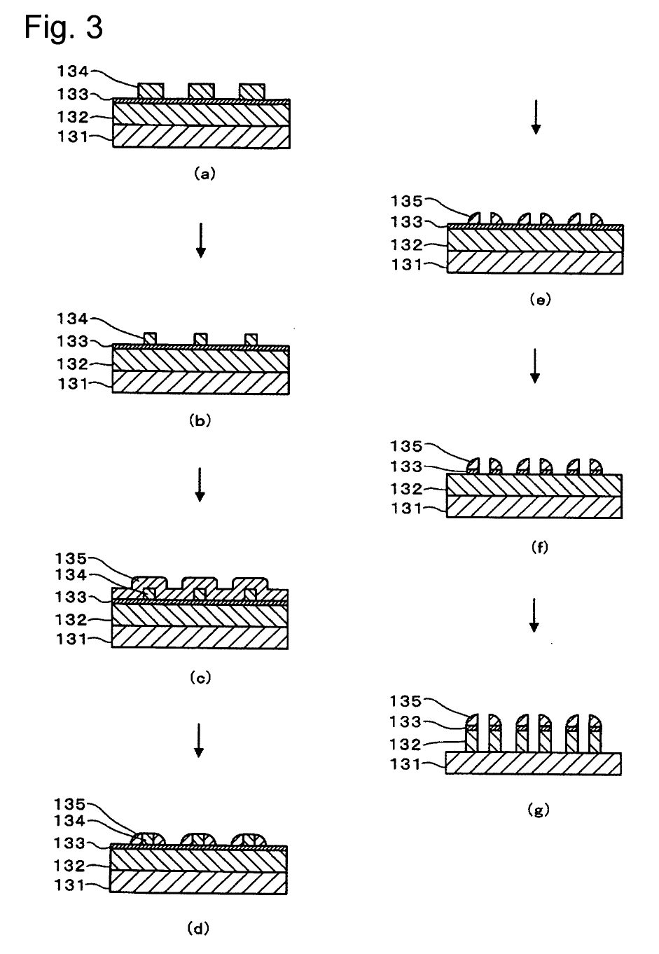

FIG. 3 illustrates the process of the manufacturing method of the semiconductor device of a third embodiment. As illustrated in FIG. 3(a), in this third embodiment, the semiconductor device is formed by, for example, SiO₂ film, a Si₃N₄ film, polysilicon, etc., and an organic membrane 132 is formed on a layer 131 for aiming at patterning to be etched. On this organic membrane 132, an SOG film (or an LTO film) 133 is formed as an antireflection film formed from an inorganic material, and photoresist 134 is formed on this SOG film (or the LTO/BARC stacked film) 133. The photoresist 134 is patterned by an exposure and development process and formed into a pattern having a predetermined shape.

FIG. 3(b) illustrates the state where trimming of the above-mentioned photoresist 134 has been conducted, and line width has been made thin. The plasma etching using oxygen plasma, etc., can perform the process for performing trimming of this photoresist 134, for example. This trimming process may be performed if needed and may be skipped, in cases where the line width of the photoresist 134 has been structured into a desired line width.

Next, as illustrated in FIG. 3(c), an SiO₂ film 135 is formed. In this membrane formation process, since the membrane is formed on photoresist 134, as mentioned above, it is preferred to form the membrane at low temperature (for example, about 300 degrees centigrade or lower), and the chemicals vapor phase epitaxy, etc., in which membrane formation gas is activated by the heating catalyst body, can perform.

Next, as illustrated in FIG. 3(d), the SiO₂ film 135 is etched and the SiO₂ film 135 changes into the state where the SiO₂ film 135 remains only in the side wall section of the pattern of the photoresist 134. This etching can be performed using, for example, mixed gas of CF series gas of CF₄, C₄F₈, CHF₃, CH₃F, and CH₂F₂, and Ar gas and/or the gas that oxygen is added if needed to this mixed gas, for example.

Next, as illustrated in FIG. 3(e), by ashing using oxygen plasma, etc., the pattern of the photoresist 134 is removed and the pattern of SiO₂ film 135 which remains in the side wall section is formed.

Then, as illustrated in FIG. 3(f), an SOG film (or an LTO/BARC stacked film) 133, which is a lower layer, is etched by using the pattern of the SiO₂ film 135 as a mask, which is described above, and as illustrated in FIG. 3 (g), organic membrane 132, which is a lower layer, is etched further. And a layer to be etched 131, which is a lower layer, is etched via the mask containing the patterned organic membrane 132. In this case, the layer to be etched 131 may be a film, which is formed by an inorganic material, which is polysilicon, etc., and others, such as an oxide film or a nitride film. Etching of the SOG film (or the LTO/BARC stacked film) 133 can be performed using, for example, mixed gas of CF series gas of CF4, C4F8, CHF3, CH3F, and CH2F2, and Ar gas and/or the gas that oxygen is added if needed to this mixed gas, for example.

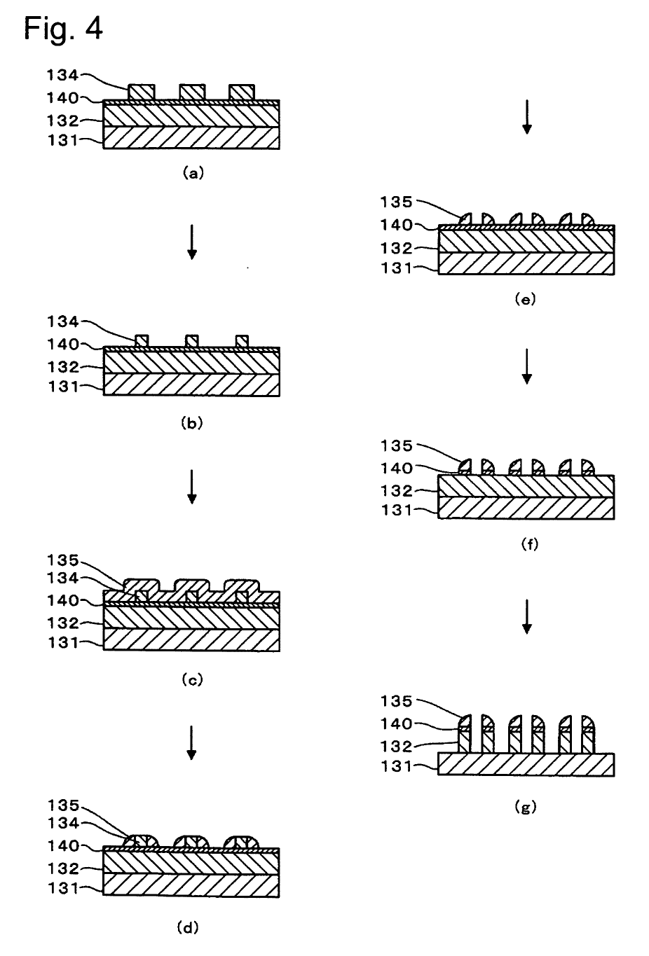

FIG. 4 illustrates the manufacturing process of the semiconductor device of a fourth embodiment with which an SiON film 140 is formed as an antireflection film instead of the SOG film (or the LTO/BARC stacked film) 133 in the above-mentioned third embodiment. In the case of this fourth embodiment, the process of FIGS. 4(a)-4(g) will be performed as well as the process illustrated in FIGS. 3(a)-3(g) in the case of the third embodiment.

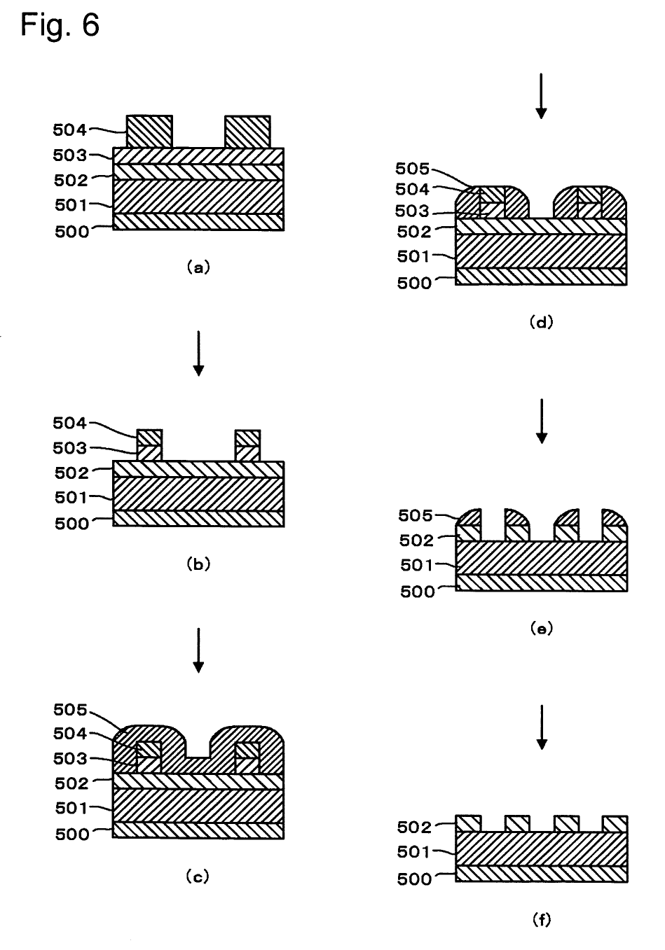

Next, the fifth embodiment will be described with reference to FIGS. 6-10. As illustrated in FIG. 6(a), in this fifth embodiment, a silicon nitride layer 501 as a second mask structure layer is formed on a silicon oxide layer 500 as a layer to be etched for aiming at patterning. On this silicon nitride layer 501, an amorphous silicon layer 502 is formed as a first mask structure layer. This amorphous silicon layer 502 may be a polysilicon layer. On this amorphous silicon layer 502, an antireflection film (BARC) 503, which is formed from an organic material, is formed. And a photoresist 504 is formed on this antireflection film (BARC) 503. The photoresist 504 is patterned by an exposure and development process and formed into a predetermined pattern (a first pattern) having a shape of a plurality of lines. As for the pattern of the line shape of this photoresist 504, the interval between lines shall be 60 nm and the width (line width) of a line shall be 60 nm, etc., for example.

FIG. 6(b) illustrates the situation where the above-mentioned photoresist 504 has been trimmed to make line width thin (for example, it may be 30 nm), and further the antireflection film (BARC) 503 has been etched. The plasma etching using oxygen plasma, etc., can perform the process of performing trimming of this photoresist 504, and etching of antireflection film (BARC) 503, for example.

Next, as illustrated in FIG. 6 (c), the first membrane formation process of forming an SiO₂ film 505 on the photoresist is performed. The chemical vapor phase epitaxy, in which membrane formation gas is activated by the heating catalyst body, performs this membrane formation process as well as the embodiment mentioned above.

Next, as illustrated in FIG. 6(d), a first etching process in which the SiO₂ film 505 is etched and the SiO₂ film 505 is changed into the state where the SiO₂ film 505 remains only in a side wall section of a pattern of photoresist 504 is performed. This etching can be performed using, for example, mixed gas of CF series gas of CF₄, C₄F₈, CHF₃, CH₃F, and CH₂F₂, and Ar gas and/or the gas that oxygen is added if needed to this mixed gas, for example.

Next, as illustrated in FIG. 6(e), by ashing using oxygen plasma, etc., the pattern of photoresist 504 is removed and a second pattern formation process of forming a pattern (a second pattern) by the SiO₂ film 505 which remained in the side wall section is performed. A second etching process, which etches the amorphous silicon layer 502 by using a pattern by this SiO₂ film 505 as a mask is performed. Etching of amorphous silicon layer 502 can be performed by using HBr gas, etc., for example.

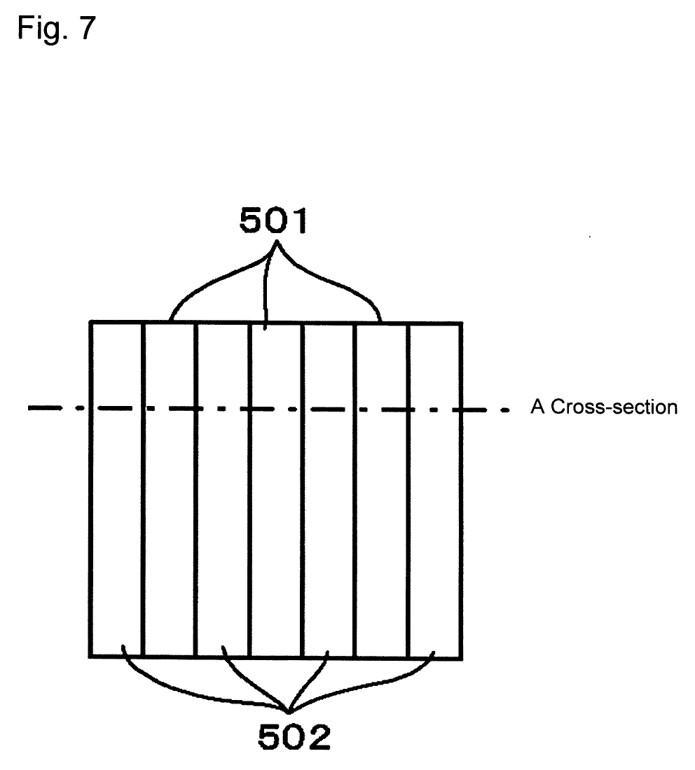

And as illustrated in FIG. 6(f), the SiO₂ film 505 used as an etching mask is removed. Based on the above process, as illustrated in the plane view of FIG. 7, when a semiconductor wafer is seen from top, an amorphous silicon layer 502 is formed in the shape of a line (line width, for example, 30 nm, and an interval, for example, 30 nm). It will be in the state where a silicon nitride layer 501, which is lower layer, is exposed between these amorphous silicon layers 502. FIG. 6(f) is a sectional view of A-section illustrated by a dashed dotted line of FIG. 7.

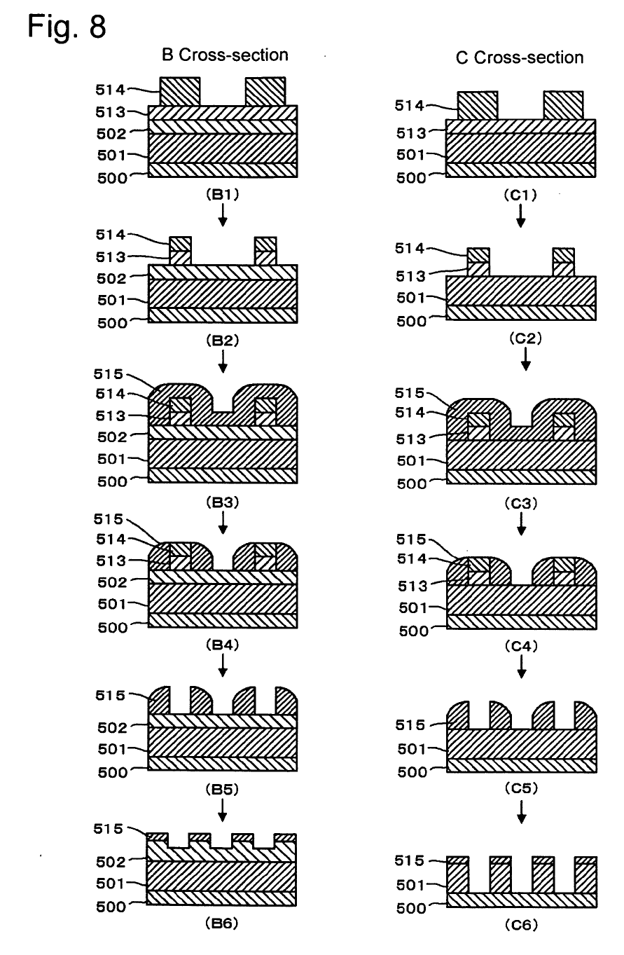

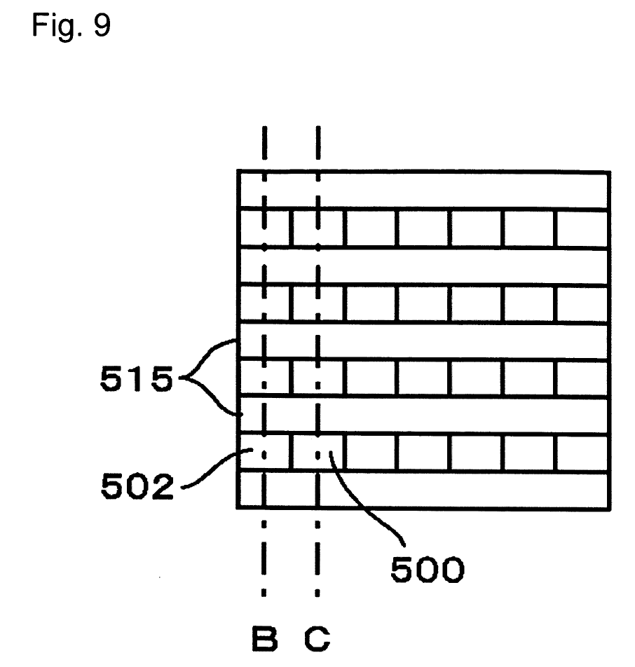

Next, from a state of above-mentioned FIG. 6 (f), as illustrated in FIGS. 8(B1) and 8(C1), an antireflection film (BARC) 513 is formed. Then, a third pattern formation process for forming a photoresist 514 (a third pattern), which is patterned according to a coating, exposure and development process on the antireflection film (BARC) 513, is performed. This photoresist 514 is a pattern having a line shape in a direction, which perpendicularly crosses with the amorphous silicon layer 502 as illustrated in FIG. 7. For example, as for this pattern, the width (line width) is 60 nm and the line interval between lines is 60 nm. Here, B-section in a plane view illustrating in FIG. 9, which will be described later, is illustrated in the left hand side in FIG. 8 and C-section is illustrated in right-hand side of FIG. 8.

FIGS. 8(B2) and 8(C2) illustrate the state where the above-mentioned photoresist 514 is trimmed to make line width thin (for example, it may be 30 nm) and the antireflection film (BARC) 513 has been etched. Plasma etching using oxygen plasma, etc., can perform a process of performing trimming of this photoresist 514, and etching of the antireflection film (BARC) 513, for example.

Next, as illustrated in FIGS. 8(B3) and 8(C3), a second membrane formation process of forming SiO₂ film 515 is performed. Chemical vapor phase epitaxy, etc., in which membrane formation gas is activated by a heating catalyst body, performs this membrane formation process as well as the embodiment mentioned above, for example.

Next, as illustrated in FIGS. 8(B4) and 8(C4), SiO₂ film is etched and a third etching process, in which SiO₂ film 515 changes into the state where the SiO₂ film 515 remains only in a side wall section of a pattern of the photoresist 514, is performed. This etching can be performed using, for example, mixed gas of CF series gas of CF₄, C₄F₈, CHF₃, CH₃F, and CH₂F₂, and Ar gas, and/or the gas that oxygen is added if needed to this mixed gas, for example.

Next, as illustrated in FIGS. 8(B5) and 8(C5), by ashing using oxygen plasma, etc., a pattern of photoresist 514 is removed and the fourth pattern formation process of forming a pattern (the fourth pattern) of SiO₂ film 515 which remained in a side wall section is performed.

Next, as illustrated in FIGS. 8(B6) and 8(C6), the fourth etching process that etches silicon nitride layer 501 is performed by using a pattern of SiO₂ film 515 and amorphous silicon layer 502 as a mask. This etching can be performed using, for example, mixed gas of CF series gas of CF₄, C₄F₈, CHF₃, CH₃F, and CH₂F₂, and Ar gas and/or the gas that oxygen is added if needed to this mixed gas, for example. Under this situation, as illustrated in a plane view of FIG. 9, when a semiconductor wafer is seen from a top, it is in the state where an area which is surrounded by amorphous silicon layer 502 having a rectangular shape between line-shaped SiO₂ film 515 and SiO₂ film 515 having this line shape, and silicon oxide layer 500 is exposed in the rectangular shape, has been formed.

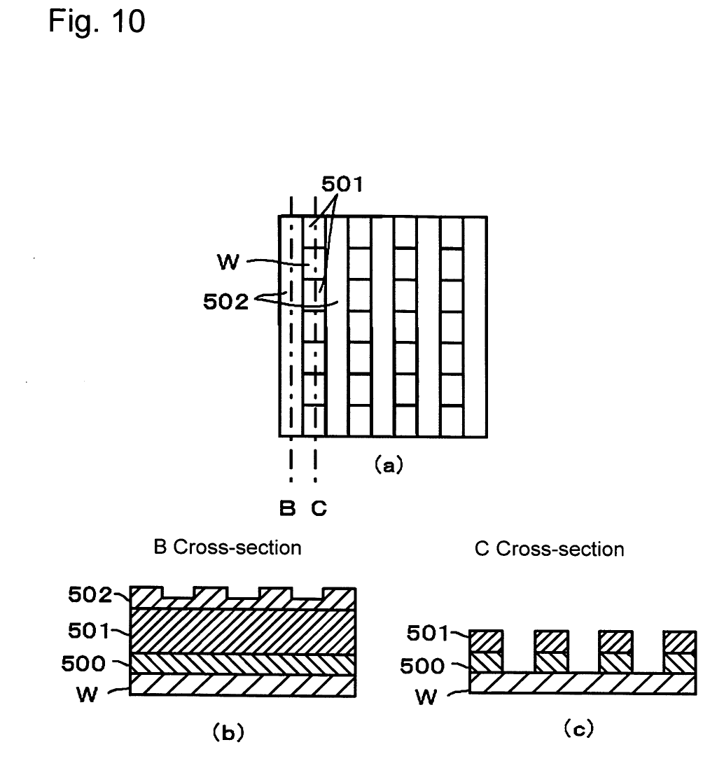

Next, as illustrated in FIG. 10, while removing SiO₂ film 515, the fifth etching process that etches silicon oxide layer 500 is performed by using amorphous silicon layer 502 and silicon nitride layer 501 as a mask. According to the above process, as illustrated in FIG. 10, a hole shape, from which the surface of silicon wafer W exposes, is formed onto silicon oxide layer 500. FIG. 10(a) is a plane view, FIG. 10(b) is a sectional view in alignment with dashed dotted line B which illustrates FIG. 10(a) and FIG. 10(c) is a sectional view in alignment with dashed dotted line C illustrated in FIG. 10(a).

According to a fifth embodiment described above, a pattern having a fine hole shape having one side of 30 nm, for example, can be formed.

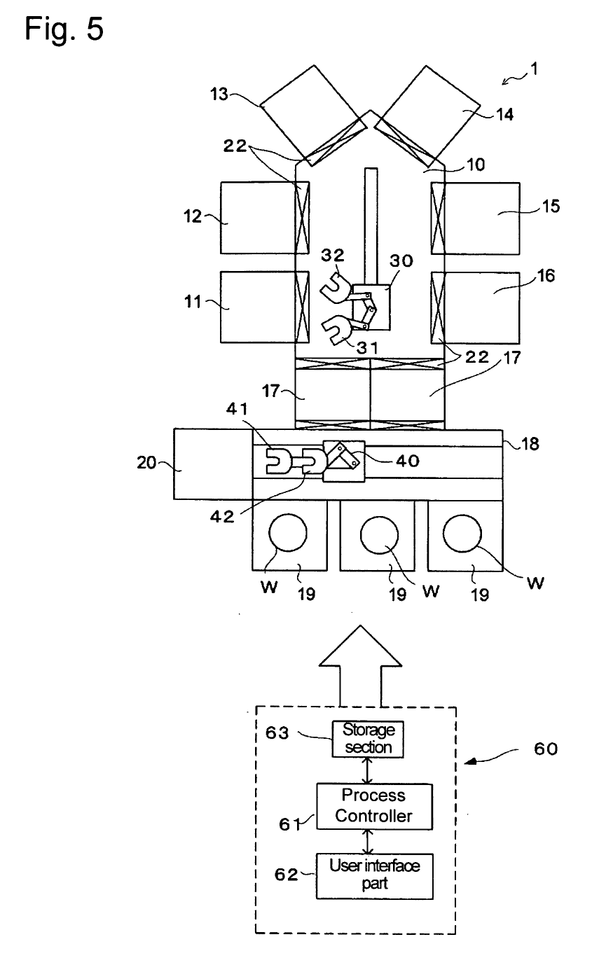

FIG. 5 is an upper surface drawing schematically illustrating an example of structure of a manufacturing apparatus of a semiconductor device for enforcing the manufacturing method of the above-mentioned semiconductor device. A vacuum conveyance chamber 10 is provided in the central portion of the manufacturing apparatus 1 of a semiconductor device. Along with this vacuum conveyance chamber 10, a plurality of processing chambers 11-16 (in this embodiment, there are six pieces) are disposed in that circumference. These processing chambers perform chemical vapor phase epitaxy in which membrane formation gas is activated inside by plasma etching and a heating catalyst body.

Two load lock chambers 17 are provided in this side (the lower side in FIG. 5) of a vacuum conveyance chamber 10. A conveyance chamber 18 for conveying a substrate (in this embodiment, a semiconductor wafer W) in the atmosphere is provided further in this side of those load lock chambers 17 (the lower side in FIG. 5). Further in this side of the conveyance chamber 18 (the lower side in FIG. 5), a plurality of placing sections 19, onto which a substrate storing case (a cassette or a hoop), into which a plurality of semiconductor wafers W can be stored, is disposed is provided (in FIG. 5, there are three placing sections). Orientor 20, which detects the position of semiconductor wafer W by an orientation flat or a notch is provided in the side of conveyance chamber 18 (left-hand side in a FIG. 5).

A gate valve 22 is respectively provided between the vacuum conveyance chamber 10 and the processing chambers 11-16, between the load lock chamber 17 and the vacuum conveyance chamber 10 and between the load lock chamber 17 and the conveyance chamber 18. Between these spaces can be arranged to be air-tightly blockaded and opened. A vacuum conveyance mechanism 30 is provided in the vacuum conveyance chamber 10. This vacuum conveyance mechanism possesses a first pick 31 and a second pick 32. The vacuum conveyance mechanism 30 is configured so that two semiconductor wafers are supported. The vacuum conveyance mechanism 30 is configured so that the semiconductor wafer W can be carried in and taken out to each processing chambers 11-16 and load lock chamber 17.

An air conveyance mechanism 40 is provided in the conveyance chamber 18. This air conveyance mechanism 40 possesses a first pick 41 and a second pick 42, and these configure the air conveyance mechanism 40 so as to be able to support two semiconductor wafers W. Air conveyance mechanism 40 is configured so that the semiconductor wafer W can be carried in and taken out to each cassette or the hoop, the load lock chamber 17 and the orientor 20, which are placed in the placing section 19.

The operation of the manufacturing apparatus 1 of the semiconductor device having the above-mentioned structure is totally controlled by a control section 60. A process controller 61, which is provided with CPU, for controlling each part of the manufacturing apparatus 1 of the semiconductor device, a user interface part 62 and a storage section 63 are provided in this control section 60.

The user interface part 62 is configured by a keyboard which performs input operation of a command in order that a process controller may control the manufacturing apparatus 1 of the semiconductor device, and a display which visualizes and displays the operation status of manufacturing apparatus 1 of the semiconductor device, etc.

The recipe with which a control program (software), processing condition data, etc., for realizing various processing executed by the manufacturing apparatus 1 of the semiconductor device through the control of the process controller 61 have been memorized is stored in a storage section 63. And when needed, arbitrary recipes are called from the storage section 63 with the directions from a user interface section 62, etc., and the process controller 61 is executed. Thereby, a desired processing by the manufacturing apparatus 1 of the semiconductor device is performed under the control of the process controller 61. Recipes, such as a control program and processing condition data, use the data in the state where the data has been stored in the program store media (for example, a hard disk, CD, a flexible disk, semiconductor memory, etc.), etc., which can be read by computers. Or it is also possible to make the data transmit at any time via a dedicated line, for example, and to use on-line from other apparatuses.

A series of processes illustrated in the first to the five embodiments can be carried out using the manufacturing apparatus 1 of a semiconductor device of the above-mentioned structure. The semiconductor wafer W may once be taken out from the manufacturing apparatus 1 of the above-mentioned semiconductor device, and other apparatus may perform a membrane formation process. Other coating applauses, exposing apparatus and a development apparatus may perform coating of photoresist, exposure and a development process.

According to embodiments of the present invention, simplification of a process and reduction of a manufacturing cost can be promoted comparing to the former. The manufacturing method of the semiconductor device, which can promote improvement in productivity, the manufacturing apparatus of a semiconductor device, a control program and a program store medium can also be provided.

What is claimed is:

1. A manufacturing method of a semiconductor device, which etches a layer to be etched on a substrate into a predetermined pattern based on a first pattern of photoresist produced by exposing and developing a photoresist film, the manufacturing method comprising the steps of:
forming an SiO₂ film on a first pattern of the photoresist;
etching the SiO₂ film so that the SiO₂ may remain only in a side wall section of a first pattern of the photoresist;
removing a first pattern of the photoresist; and
forming a second pattern of the SiO₂ film.

2. The manufacturing method of a semiconductor device of claim 1,
wherein the step of forming an SiO₂ film is performed by applying chemical vapor phase epitaxy by using membrane formation gas activated by a heating catalyst body.

3. The manufacturing method of a semiconductor device of claim 1 further comprising the steps of:
trimming a first pattern of the photoresist while etching an antireflection film formed from an organic material, which is a lower layer, before forming an SiO₂ film.

4. The manufacturing method of a semiconductor device of claim 1,
wherein a silicon layer, a silicon nitride layer or a silicon oxynitride layer, which is a lower layer, is etched by using the second pattern as a mask after the step of forming a second pattern.

5. The manufacturing method of a semiconductor device of claim 1 further comprising the steps of:
etching an antireflection film formed from an inorganic material, which is a lower layer, by using the second pattern as a mask after forming the second pattern; and
then, etching an inorganic material film, which is a lower layer than an antireflection film formed from the organic material.

6. The manufacturing method of a semiconductor device of claim 5,
wherein an antireflection film formed from the inorganic material is an SOG film, an LTO film or an SiON film.

7. A manufacturing method of a semiconductor device, which etches a layer to be etched on a substrate into a predetermined pattern, the manufacturing method comprising the steps of:
forming a first pattern formed from a plurality of line-shaped patterns of photoresist;
forming an SiO₂ film on the first pattern;
etching the SiO₂ film on the first pattern so that the SiO₂ film on the first pattern may remain only in a side wall section of a first pattern of the photoresist;
removing the first pattern and forming a second pattern of the SiO₂ film;
etching a first mask structure layer, which is a lower layer, by using the second pattern as a mask;
forming a third pattern formed from a plurality of line-shaped patterns of photoresist in a direction which perpendicularly crosses to the first pattern;
forming a SiO₂ film on the third pattern;
etching the SiO₂ film on the third pattern so that the SiO₂ film on the third pattern may remain only in a side wall section of the third pattern;
removing the third pattern and forming a fourth pattern of the SiO₂ film;
etching a second mask structure layer, which is a lower layer, by using the fourth pattern and the first mask structure layer as a mask; and
forming a hole shape in the layer to be etched by using the first mask structure layer and the second mask structure layer as a mask.

8. The manufacturing method of a semiconductor device of claim 7,
wherein the steps of forming an SiO₂ film on the first pattern and etching the first mask structure and forming a second pattern of the SiO₂ film are performed by applying chemical vapor phase epitaxy by using membrane formation gas activated by a heating catalyst body.

9. The manufacturing method of a semiconductor device of claim 7, further comprising the steps of:
trimming the first pattern before forming an SiO₂ film on the first pattern, while etching an antireflection film formed from an organic material, which is a lower layer; and
trimming the third pattern before forming a second pattern of the SiO₂ film while etching an antireflection film formed from an organic material, which is a lower layer.

10. The manufacturing method of a semiconductor device of claim 7,
wherein the first mask structure layer is formed from silicon and the second mask structure layer is formed from silicon nitride.

11. A manufacturing apparatus of a semiconductor device, which manufactures a semiconductor device by etching a layer to be etched on a substrate into a predetermined pattern, the manufacturing apparatus comprising:
a processing chamber for storing the substrate;
a processing gas supply means, which supplies processing gas into the processing chamber; and
a control section for controlling the processing gas supply means so that the manufacturing method of a semiconductor device as in any one of claims 1-6, is performed within the processing chamber.

12. A control program for operating on a computer and controlling a manufacturing apparatus of a semiconductor device at time of execution so that the manufacturing method of the semiconductor device of claims 1 is performed.

13. A program store medium, which is a medium by which a control program, which operates on a computer, is memorized, the control program controlling a manufacturing apparatus of a semiconductor device so that the manufacturing method of the semiconductor device of claim 1 is performed at time of execution.
